(19) United States
(12) Patent Application Publication
(10) Pub. No.: US 2022/0095458 A1
(43) Pub. Date: Mar. 24, 2022

(54) PRINTED CIRCUIT BOARD

(71) Applicant: SAMSUNG ELECTRO-MECHANICS CO., LTD., Suwon-si (KR)

(72) Inventors: Jung Soo KIM, Suwon-si (KR); Dae Jung BYUN, Suwon-si (KR); Chang Min HA, Suwon-si (KR); Sang Hyun SIM, Suwon-si (KR)

(21) Appl. No.: 17/124,814

(22) Filed: Dec. 17, 2020

(30) Foreign Application Priority Data
Sep. 24, 2020 (KR) 10-2020-0123778

(51) Int. Cl. H05K 1/11; H05K 1/02

(52) U.S. Cl. CPC H05K 1/118; H05K 1/115; H05K 1/0281

(57) ABSTRACT

A printed circuit board includes a first insulating layer disposed on a flexible region and a rigid region; and a first wiring layer disposed on one surface of the first insulating layer in the rigid region and the flexible region. A thickness of the first wiring layer in at least a portion of the rigid region is greater than a thickness of the first wiring layer in the flexible region.

### CROSS-REFERENCE TO RELATED APPLICATION(S)

This application claims benefit of priority to Korean Patent Application No. 10-2020-0123778 filed on Sep. 24, 2020 in the Korean Intellectual Property Office, the disclosure of which is incorporated herein by reference in its entirety.

### TECHNICAL FIELD

The present disclosure relates to a printed circuit board.

### BACKGROUND

When a via is formed on a printed circuit board by plating, a button plating method in which plating is performed only on a via hole region and no plating is performed on other regions may sometimes be applied.

Since such a button plating method has a very narrow plating area, it may be difficult to perform stable plating. In particular, when a plating layer is formed to have a thickness greater than a thickness of a plating resist, there may be a problem in which the plating layer covers the plating resist, and overhang defects easily occur.

In addition, when a dry film is not sufficiently adhered due to a step difference in plating thickness between a via land region and other regions, an etching solution may penetrate into the via land region to generate via opening defects.

In the meantime, in a printed circuit board including a rigid region and a flexible region, when a crack occurs in a wiring pattern in a region adjacent to a boundary between the rigid region and the flexible region, there may be a problem in which disconnection of a wiring layer occurs.

### SUMMARY

An aspect of the present disclosure is to provide a printed circuit board capable of preventing the occurrence of overhang defects.

Another aspect of the present disclosure is to provide a printed circuit board capable of preventing the occurrence of via opening defects.

Another aspect of the present disclosure is to provide a printed circuit board capable of preventing the occurrence of disconnection of a wiring layer.

According to an aspect of the present disclosure, a printed circuit board includes a first insulating layer disposed on a flexible region and a rigid region; and a first wiring layer disposed on one surface of the first insulating layer in the rigid region and the flexible region. A thickness of the first wiring layer in at least a portion of the rigid region is greater than a thickness of the first wiring layer in the flexible region.

According to another aspect of the present disclosure, a printed circuit board includes a first insulating layer disposed on a flexible region and a rigid region; and a wiring pattern disposed on one surface of the first insulating layer in the rigid region and the flexible region. A width of the wiring pattern at a boundary between the flexible region and the rigid region is wider than a width of the wiring pattern in the flexible region and a width of the wiring pattern in the rigid region, respectively.

According to another aspect of the present disclosure, a printed circuit board includes a first insulating layer disposed on a flexible region and a rigid region; a first metal layer disposed on one surface of the first insulating layer in the rigid region and the flexible region; a second metal layer disposed in the rigid region; and a via extending from the second metal layer into the first insulating layer. A first pattern of the first metal layer and a second pattern of the second metal layer are connected to the via and are contiguous.

According to another aspect of the present disclosure, a printed circuit board includes a first insulating layer; a first metal layer disposed on one surface of the first insulating layer; a second metal layer disposed on the first metal layer; a third metal layer disposed on another surface of the first insulating layer; a second insulating layer disposed on the one surface of the first insulating layer to cover the second metal layer; a third insulating layer disposed on the another surface of the first insulating layer to cover the third metal layer; and a via extending in the first insulating layer from the third metal layer to second metal layer. A first pattern of the first metal layer and a second pattern of the second metal layer are connected to the via and are contiguous.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board according to the present disclosure;

FIGS. 4A to 4D are plan views schematically illustrating an enlarged view of portion A of a printed circuit board according to the present disclosure;

FIG. 5 is a cross-sectional view schematically illustrating another example of a printed circuit board according to the present disclosure;

FIG. 6 is a cross-sectional view schematically illustrating another example of a printed circuit board according to the present disclosure;

FIG. 7 is a cross-sectional view schematically illustrating another example of a printed circuit board according to the present disclosure;

FIG. 8 is a cross-sectional view schematically illustrating another example of a printed circuit board according to the present disclosure;

FIG. 9 is a cross-sectional view schematically illustrating another example of a printed circuit board according to the present disclosure;

FIG. 10 is a cross-sectional view schematically illustrating another example of a printed circuit board according to the present disclosure;

FIG. 11 is a cross-sectional view schematically illustrating another example of a printed circuit board according to the present disclosure; and

FIGS. 12A to 12H are cross-sectional views schematically illustrating a portion of a manufacturing process of a printed circuit board according to the present disclosure.

### DETAILED DESCRIPTION

Hereinafter, the present disclosure will be described with reference to the accompanying drawings. Shape and size of the elements in the drawings may be exaggerated or reduced for more clear description.

Electronics

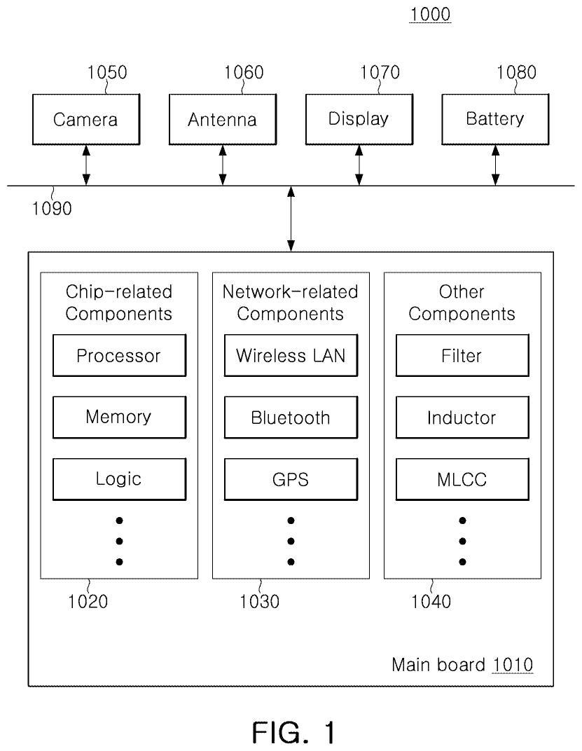

FIG. 1 is a block diagram schematically illustrating an example of an electronic device system.

Referring to the drawings, an electronic device 1000 may accommodate a main board 1010 therein. The main board 1010 may include chip related components 1020, network related components 1030, other components 1040, and the like, physically and/or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter, an application-specific integrated circuit (ASIC), or the like. However, the chip related components 1020 are not limited thereto, but may also include other types of chip related components. In addition, the chip related components 1020 may be combined with each other. The chip related component 1020 may be in the form of a package including the above-described chip or an electronic component.

The network related components 1030 may include components compatible with or communicating using various protocols such as wireless fidelity (Wi-Fi) (Institute of Electrical and Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include components compatible with or communicating using a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 and/or the network related components 1030 described above.

Depending on a type of the electronic device 1000, the electronic device 1000 may include other components that may or may not be physically and/or electrically connected to the main board 1010. These other components may include, for example, a camera module 1050, an antenna module 1060, a display device 1070, a battery 1080, or the like. However, these other components are not limited thereto, but may also include an audio codec, a video codec, a power amplifier, a compass, an accelerometer, a gyroscope, a speaker, amass storage unit (for example, a hard disk drive), a compact disk (CD) drive, a digital versatile disk (DVD) drive, or the like. These other components may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

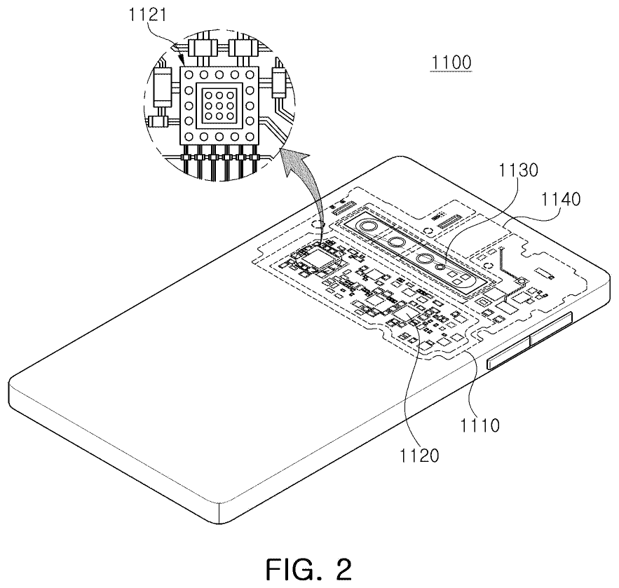

FIG. 2 is a perspective view schematically illustrating an example of an electronic device.

Referring to the drawings, an electronic device may be, for example, a smartphone 1100. A main board 1110 may be accommodated in the smartphone 1100, and various electronic components 1120 may be physically and/or electrically connected to the main board 1110. In addition, other electronic components, such as a camera module 1130 and/or a speaker 1140, which may or may not be physically and/or electrically connected to the main board 1110 may be accommodated therein. A portion of the electronic components 1120 may be the above-described chip related components, for example, an antenna module 1121, but are not limited thereto. The antenna module 1121 may be provided as a surface-mounted form in which a semiconductor chip or a passive component is mounted on a printed circuit board, but is not limited thereto. The electronic device is not necessarily limited to the smartphone 1100, but may be other electronic devices as described above.

Printed Circuit Board

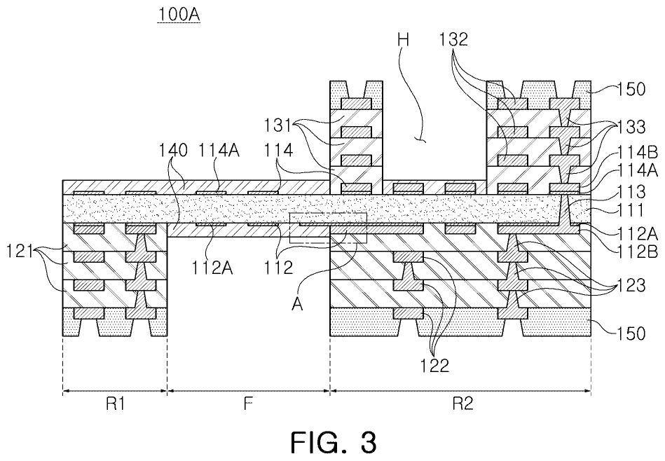

FIG. 3 is a cross-sectional view schematically illustrating an example of a printed circuit board according to the present disclosure.

Referring to the drawings, a printed circuit board 100A according to an example has rigid regions R1 and R2 and a flexible region F.

In addition, a printed circuit board 100A according to an example may include a first insulating layer 111, a first wiring layer 112, a second wiring layer 114, and a first via 113. In addition, a printed circuit board 100A according to an example may further include at least one of a second insulating layer 121, a third wiring layer 122, a second via 123, a third insulating layer 131, a fourth wiring layer 132, a fourth wiring layer 132, and a third via 133. In addition, a printed circuit board 100A according to an example may further include a coverlay 140 and/or a protective layer 150.

Ina printed circuit board 100A according to an example, a thickness of the first wiring layer 112 in at least a portion of the rigid regions R1 and R2 may be greater than a thickness of the first wiring layer 112 in the flexible region F. Therefore, there may be a step difference between the first wiring layer 112 in the at least a portion of the rigid regions R1 and R2 and the first wiring layer 112 in the flexible region F.

In this case, the expression of “at least a portion of the rigid regions R1 and R2” is not limited to the meaning of one of a plurality of rigid regions that may be spaced apart from each other, and refers to a partial region of the singular number of rigid regions R1 or R2.

In the drawings, a thickness of the first wiring layer 112 in the entire regions of the rigid regions R1 and R2 is illustrated as being greater than a thickness of the first wiring layer 112 in the flexible region F, but is not limited thereto. As a non-limiting example, a thickness of the first wiring layer 112 only in a portion of the second rigid region R2 may be greater than a thickness of the first wiring layer 112 in the flexible region F.

In this case, the first wiring layer 112 in the flexible region F may include a first metal layer 112A, and the first wiring layer 112 in the at least a portion of the rigid regions R1 and R2 may include the first metal layer 112A and a second metal layer 112B. Therefore, a thickness of the first wiring layer 112 in the at least a portion of the rigid regions R1 and R2 may be greater than a thickness of the first wiring layer 112 in the flexible region F.

When a via is formed on a printed circuit board by plating, a button plating method in which plating is performed only on a via hole region and no plating is performed on other regions may be sometimes applied. Since such a button plating method has a very narrow plating area, it may be difficult to perform stable plating. In particular, when a plating layer is formed to have a thickness greater than a thickness of a plating resist, there may be a problem in which the plating layer covers the plating resist, and overhang defects may easily occur. In addition, when a dry film is not sufficiently adhered, due to a step difference in plating thickness between a via land region and other regions, an etching solution may penetrate into the via land region to generate via opening defects.

In a printed circuit board 100A according to the present disclosure, since plating may be performed on the rigid regions R1 and R2 overall, the first wiring layer 112 in the flexible region F may include the first metal layer 112A, and the first wiring layer 112 in the rigid regions R1 and R2 may include the first metal layer 112A and the second metal layer 112B. Thereby, it is possible to prevent overhang defects and via opening defects, which may be problems that may occur when applying a button plating method in which plating is performed only on a via hole region. However, as will be described later, it may not be necessary to perform plating on the rigid regions R1 and R2 overall, and it is also possible to perform plating on only a portion of the rigid regions R1 and R2, which may be wider than the via hole region to prevent overhang defects and via opening defects.

Hereinafter, components of a printed circuit board 100A according to an example will be described in more detail.

A printed circuit board 100A according to an example may have rigid regions R1 and R2 and a flexible region F. In the drawings, the printed circuit board 100A according to an example is illustrated to have a plurality of rigid regions R1 and R2 spaced apart from each other, but the number of rigid regions is not particularly limited. For example, a printed circuit board 100A according to an example may have only one rigid region, and may have a larger number of rigid regions than those illustrated in the drawings. Also, the number of flexible regions F is not particularly limited. A printed circuit board 100A according to an example may have two or more flexible regions F.

The flexible region F refers to a region that may be relatively bent or easier to fold than the rigid regions R1 and R2. The rigid regions R1 and R2 refer to regions that may not be relatively bent or be easier to fold than the flexible region F. However, the expressions of the flexible region F and the rigid region (e.g., R1 and R2) may be introduced to describe relative characteristics between the two regions, and it may not be interpreted to limit regions in which the rigid regions R1 and R2 are not bent or folded.

As described later, a printed circuit board 100A according to an example may further include a second insulating layer 121 and/or a third insulating layer 131 disposed on the one surface of the first insulating layer 111. In this case, in the printed circuit board 100A according to an example, the second insulating layer 121 and/or the third insulating layer 131 may be further disposed on the first insulating layer 111 to have the rigid regions R1 and R2. Specifically, the rigid regions R1 and R2 in which the second insulating layer 121 and/or the third insulating layer 131 are arranged may have a thickness greater than a thickness in the flexible region F in which the second insulating layer 121 and/or the third insulating layer 131 are not arranged, to have a rigid characteristic. Alternatively, the rigid regions R1 and R2 in which the second insulating layer 121 and/or the third insulating layer 131 are arranged may include the second insulating layer 121 and/or the third insulating layer 131 having a more rigid characteristic, as compared to the first insulating layer 111 disposed in the flexible region F in which the second insulating layer 121 and/or the third insulating layer 131 are not arranged, to have a rigid characteristic.

A printed circuit board 100A according to an example may include a first insulating layer 111, a first wiring layer 112 disposed on one surface of the first insulating layer 111, a second wiring layer 114 disposed on the other surface of the first insulating layer 111 in the rigid region, opposite to the one surface of the first insulating layer 111, and a first via 113 passing through the first insulating layer 111 and connecting the first wiring layer 112 and the second wiring layer 114.

As a material for forming the first insulating layer 111, an insulating material may be used without limitation. As the material for forming the first insulating layer 111, a material having a low elastic modulus may be used to have flexible characteristics. For example, an elastic modulus of the first insulating layer 111 may be lower than an elastic modulus of the second insulating layer 121 and/or an elastic modulus of the third insulating layer 131. However, the present disclosure is not limited thereto, and an elastic modulus of the first insulating layer 111 may be similar to or the same as an elastic modulus of the second insulating layer 121 and/or an elastic modulus of the third insulating layer 131.

For example, as the material for forming the first insulating layer 111, polyimide (PI), polyethylene terephthalate (PET), polyethylene naphthalate (PEN), polycarbonate (PC), polyethersulfone (PES), polyacrylate (PAR), liquid crystal polymer (LCP), or the like may be used, but are not limited thereto. In addition, as the material for forming the first insulating layer 111, a reinforcing material such as a glass fiber, a filler, and/or the like may not be included. The material for forming the first insulating layer 111 may include the same material as, or may include materials different from a material for forming the second insulating layer 121 and/or a material for forming the third insulating layer 131.

In the drawings, the first insulating layer 111 is illustrated as being provided as a single first insulating layer 111, but the number of the first insulating layers 111 is not particularly limited. When the first insulating layer 111 is provided as a plurality of first insulating layers 111, a material, a thickness, or the like of the plurality of first insulating layers 111 may be the same or different from each other.

The first wiring layer 112 may be disposed on the one surface of the first insulating layer 111. The first wiring layer 112 may perform various functions according to a design of the corresponding layer. For example, the first wiring layer 112 may include a wiring pattern such as a ground pattern, a power pattern, a signal pattern, or the like. In this case, the signal pattern may include patterns for transmitting various signals, except for the ground pattern, the power pattern, and the like, for example, an antenna signal, a data signal, or the like. Each of these wiring patterns may include a line pattern, a plane pattern, and/or a pad pattern.

The first wiring layer 112 may include a first metal layer 112A and a second metal layer 112B. Specifically, the first wiring layer 112 in the flexible region F may include a first metal layer 112A, and the first wiring layer 112 in the at least a portion of the rigid regions R1 and R2 may include the first metal layer 112A and a second metal layer 112B.

The first metal layer 112A may be a thin metal foil, and may serve as a seed layer for forming the second metal layer 112B. In this case, a thickness of the first metal layer 112A may be thinner than a thickness of the second metal layer 112B. In addition, in the rigid region R1, the rigid region R2, or both, the second metal layer 112B may have a shape corresponding to the first metal layer 112A. In one example, a pattern of the first metal layer 112A and a pattern of the second metal layer 112B, connected to the first via 113, may be contiguous or conterminous with each other.

The second metal layer 112B may be a plating layer formed on the first metal layer 112A by plating. The second metal layer 112B may be, for example, an electroplating layer formed by electroplating.

As a material for forming each of the first and second metal layers 112A and 112B, copper (Cu), aluminum (Al), silver (Ag), tin (Sn), gold (Au), nickel (Ni), lead (Pb), titanium (Ti), or alloys thereof, or the like may be used. Materials for forming the first metal layer 112A and the second metal layer 112B may include the same material, or may include different materials.

The second wiring layer 114 may be disposed on the other surface of the first insulating layer 111, opposite to the one surface of the first insulating layer 111. The second wiring layer 114 may also include a first metal layer 114A and a second metal layer 114B. For example, as illustrated in the drawings, the second wiring layer 114 in the flexible region F may include a first metal layer 114A, and the second wiring layer 114 in the at least a portion R2 of the rigid regions R1 and R2 Reference numeral 114 may include a first metal layer 114A and a second metal layer 114B. However, the present disclosure is not limited thereto, and the second wiring layer 114 in the flexible region F may include the first metal layer 114A and the second metal layer 114B according to a design. According to a design, the second wiring layer 114 may include the first metal layer 114A and the second metal layer 114B in the rigid regions R1 and R2 overall, or may include only the first metal layer 114A in the rigid regions R1 and R2 overall.

The first metal layer 114A may be a thin metal foil, and may serve as a seed layer for forming the second metal layer 114B. In this case, a thickness of the first metal layer 114A may be thinner than a thickness of the second metal layer 114B.

The second metal layer 114B may be a plating layer formed on the first metal layer 114A by plating. The second metal layer 114B may be, for example, an electroplating layer formed by electroplating. In this case, a thickness of the second metal layer 114B may be greater than a thickness of the first metal layer 114A. In addition, the second metal layer 114B may have a shape corresponding to the first metal layer 114A.

As a material for forming each of the first and second metal layers 114A and 114B, copper (Cu), aluminum (Al), silver (Ag), tin (Sn), gold (Au), nickel (Ni), lead (Pb), titanium (Ti), or alloys thereof, or the like may be used. Materials for forming the first metal layer 114A and the second metal layer 114B may include the same material, or may include different materials.

The first via 113 may pass through the first insulating layer 111, and may connect the first wiring layer 112 and the second wiring layer 114. The first via 113 may perform various functions according to a design of the corresponding layer. For example, the first via 113 may include a via for signal connection, a via for ground connection, a via for power connection, or the like.

A conductive material may be used as a material for forming the first via 113, and, as a non-limiting example thereof, copper (Cu), aluminum (Al), silver (Ag), tin (Sn), gold (Au), nickel (Ni), lead (Pb), titanium (Ti), or alloys thereof, or the like may be used. The first via 113 may include vias in which a metal material is completely filled in a via hole, or in which a metal material is formed only along a wall surface of a via hole. The first via 113 may have a known shape such as a tapered shape, an hourglass shape, a cylindrical shape, or the like. When the first via 113 has a tapered shape, a direction to be tapered may be changed according to design.

The first via 113 may be formed through a known plating process. In this case, the first via 113 may be formed simultaneously with the second metal layer 112B, and thus the first via 113 may be integrated with the second metal layer 112B.

In addition, a printed circuit board 100A according to an example may further include at least one of a second insulating layer 121 disposed on the one surface of the first insulating layer 111 to cover the first wiring layer 112, a third wiring layer 122 disposed on the second insulating layer 121, and a second via 123 passing through the second insulating layer 121 and connected to the third wiring layer 122.

As a material for forming the second insulating layer 121, a material having insulating properties may be used without limitation. For example, as a material for forming the second insulating layer 121, a material including a thermosetting resin such as an epoxy resin, a thermoplastic resin such as polyimide, or a reinforcing material such as a glass fiber, a glass cloth, or a glass fabric and/or an inorganic filler, together with these, for example, a prepreg, Ajinomoto build-up film (ABF), photoimageable dielectric (PID), or the like may be used. However, the present disclosure is not limited thereto, and the same material as the material for forming the first insulating layer 111 may be used as a material for forming the second insulating layer 121.

In the drawings, the second insulating layer 121 is illustrated as being provided as a single second insulating layer 121, but the number of the second insulating layers 121 is not particularly limited. When the second insulating layer 121 is provided as a plurality of second insulating layers 121, a material, a thickness, or the like of the plurality of second insulating layers 121 may be the same or different from each other.

The third wiring layer 122 may perform various functions according to a design of the corresponding layer. For example, the third wiring layer 122 may include a wiring pattern such as a ground pattern, a power pattern, a signal pattern, or the like. In this case, the signal pattern may include patterns for transmitting various signals, except for the ground pattern, the power pattern, and the like, for example, an antenna signal, a data signal, or the like. Each of these wiring patterns may include a line pattern, a plane pattern, and/or a pad pattern.

The third wiring layer 122 may be formed through a known plating process. A conductive material may be used as a material for forming the third wiring layer 122, and, as a non-limiting example, copper (Cu), aluminum (Al), silver (Ag), tin (Sn), gold (Au), nickel (Ni), lead (Pb), titanium (Ti), or alloys thereof, or the like may be used.

In the drawings, the third wiring layer 122 is illustrated as being provided as a single layer, but is not limited thereto. The third wiring layer 122 may be provided as a plurality of metal layers according to a method of forming the third wiring layer 122. For example, the third wiring layer 122 may include a first metal layer serving as a seed layer and a second metal layer formed on the first metal layer by a plating process such as electroplating or the like.

The second via 123 may perform various functions according to the design of the corresponding layer. For example, the second via 123 may include a via for signal connection, a via for ground connection, a via for power connection, or the like.

In the drawings, the second via 123 is illustrated as being provided as a single layer, but is not limited thereto. The second via 123 may be provided as a plurality of metal layers according to a method of forming the second via 123. For example, the second via 123 may include a first metal layer disposed on a wall surface of a via hole to serve as a seed layer, and a second metal layer formed on the first metal layer by a plating process such as electroplating or the like.

The third wiring layer 122 and the second via 123 may be simultaneously formed through the same plating process, and thus the third wiring layer 122 and the second via 123 may be integrated.

In addition, a printed circuit board 100A according to an example may further include at least one of a third insulating layer 131 disposed on the other surface of the first insulating layer 111 to cover the second wiring layer 114, a fourth wiring layer 132 disposed on the third insulating layer 131, and a third via 133 passing through the third insulating layer 131 and connected to the fourth wiring layer 132.

Since a description of each of the third insulating layer 131, the fourth wiring layer 132, and the third via 133 may be identically applied to a description of each of the second insulating layer 121, the third wiring layer 122, and the second via 123, detailed descriptions thereof will be omitted.

The third insulating layer 131 may have a through portion H. The through portion H may be formed to expose the second wiring layer 114. When an electronic component is disposed in the through portion H, the electronic component may be connected to the second wiring layer 114.

A printed circuit board 100A according to an example may be further include a coverlay 140 disposed on the first insulating layer 111 in the flexible region F to cover at least a portion of the first wiring layer 112 and/or at least a portion of the second wiring layer 114. As necessary, the coverlay 140 may be formed to extend to the rigid regions R1 and R2, or the coverlay 140 may also be formed in the rigid regions R1 and R2.

The coverlay 140 may prevent the first wiring layer 112 and/or the second wiring layer 114 from being exposed externally, to serve to protect the first wiring layer 112 and/or the second wiring layer 114.

A printed circuit board 100A according to an example may further include a protective layer 150 disposed on the second insulating layer 121 and/or the third insulating layer 131 and having an opening exposing at least a portion of each of the third wiring layer 122 and/or the fourth wiring layer 132.

The protective layer 150 may be an Ajinomoto build-up film (ABF) layer, or may be a solder resist (SR) layer. However, the present disclosure is not limited thereto, and a known insulating material may be used as a material for forming the protective layer 150.

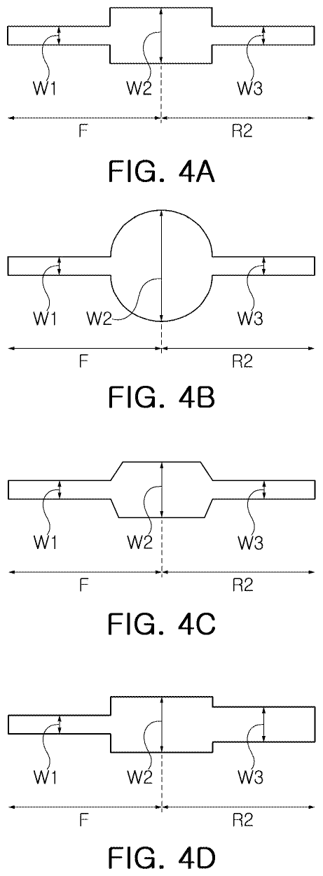

FIGS. 4A to 4D are plan views schematically illustrating an enlarged view of portion A of a printed circuit board according to the present disclosure.

Referring to the drawings, the first wiring layer 112 may include a wiring pattern extending to and disposed in the flexible region F and the rigid region R2. In this case, the wiring pattern may be formed to have a relatively wide width in a region adjacent to a boundary between the flexible region F and the rigid region R2. Therefore, the width of the wiring pattern at the boundary between the flexible region F and the rigid region R2 may be wider than a width W1 of the wiring pattern in the flexible region F and a width of the wiring pattern in the rigid region R2, respectively. Also, the wiring pattern may have a maximum width at the boundary between the flexible region F and the rigid region R2.

Therefore, the wiring pattern of the first wiring layer 112 may include a region in which a width in at least one region of the flexible region F and the rigid region R2 increases toward the boundary between the flexible region F and the rigid region R2. For example, the wiring pattern of the first wiring layer 112 may include a first region in which a width in the flexible region F increases toward the boundary between the flexible region F and the rigid region R2, and a second region in which a width in the rigid region R2 increases toward the boundary between the flexible region F and the rigid region R2.

In this case, a width of the wiring pattern may increase rapidly or may increase gradually. In addition, the wiring pattern of the first wiring layer 112 may further include a region in which a width in at least one region of the flexible region F and the rigid region R2 decreases toward the boundary between the flexible region F and the rigid region R2.

FIGS. 4A to 4D illustrate specific shapes of the wiring pattern of the first wiring layer 112 as an example. As illustrated in FIGS. 4A to 4C, the wiring pattern of the first wiring layer 112 may have a shape in which polygons such as a rectangle, a hexagon, or the like are connected, and in addition, may have a shape in which a circle, an ellipse, or the like are connected. However, these shapes are only illustrative, and shapes of the wiring pattern of the first wiring layer 112 are not limited to the shapes illustrated in the drawings.

In addition, as illustrated in FIG. 4D, a width W1 of the wiring pattern of the first wiring layer 112 in the flexible region F may be different from a width W3 of the wiring pattern of the first wiring layer 112 in the rigid region R2. However, the present disclosure is not limited thereto, and as illustrated in FIGS. 4A to 4C, a width W1 of the wiring pattern of the first wiring layer 112 in the flexible region F may be the same as a width W3 of the wiring pattern of the first wiring layer 112 in the rigid region R2.

In a printed circuit board including a rigid region and a flexible region, when a crack occurs in a wiring pattern in a region adjacent to a boundary between the rigid region and the flexible region, there may be a problem in which disconnection of a wiring layer occurs.

In a printed circuit board 100A according to the present disclosure, a width of a wiring pattern in a region adjacent to a boundary between a flexible region F and a rigid region R2 may be widen to prevent disconnection of a wiring layer due to a crack of the wiring pattern.

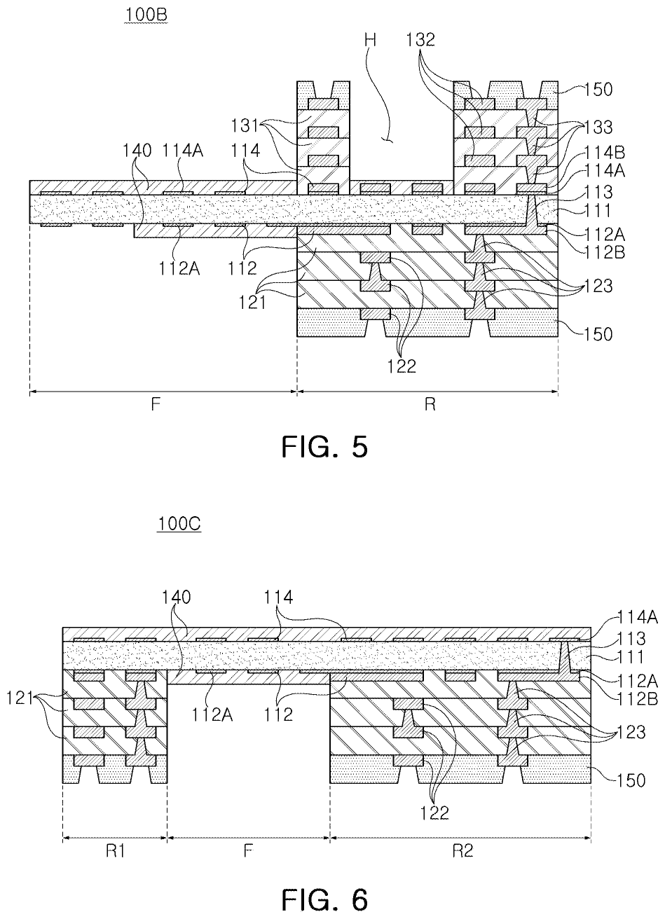

FIG. 5 is a cross-sectional view schematically illustrating another example of a printed circuit board according to the present disclosure.

Referring to the drawings, a printed circuit board 100B according to another example may include only a rigid region R, as compared to the printed circuit board 100A according to the example. Therefore, in the printed circuit board 100B according to another example, a second insulating layer 121 and/or a third insulating layer 131 may be disposed only in the rigid region R.

This is illustrative that a printed circuit board according to the present disclosure may be deformed to have various forms, and the printed circuit board according to the present disclosure is not limited to the printed circuit board illustrated in the drawings.

Since other descriptions may be applied in the same manner as the descriptions of the printed circuit board 100A according to an example, detailed descriptions thereof will be omitted.

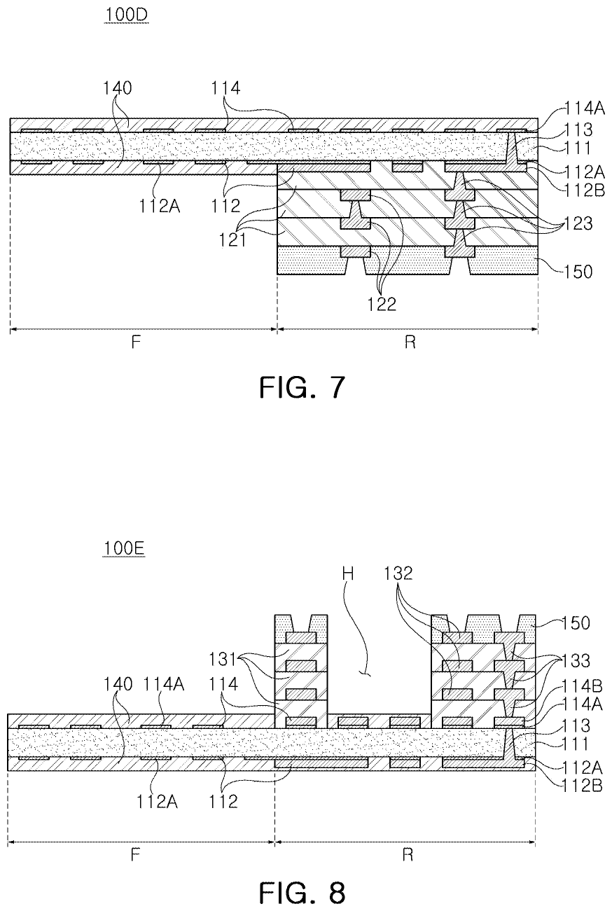

FIG. 6 is a cross-sectional view schematically illustrating another example of a printed circuit board according to the present disclosure.

Referring to the drawings, a printed circuit board 100C according to another example may not include a third insulating layer 131, a fourth wiring layer 132, and a third via 133, as compared to the printed circuit board 100A according to the example.

This is illustrative that a printed circuit board according to the present disclosure may be deformed to have various forms, and the printed circuit board according to the present disclosure is not limited to the printed circuit board illustrated in the drawings.

Since other descriptions may be applied in the same manner as the descriptions of the printed circuit board 100A according to an example, detailed descriptions thereof will be omitted.

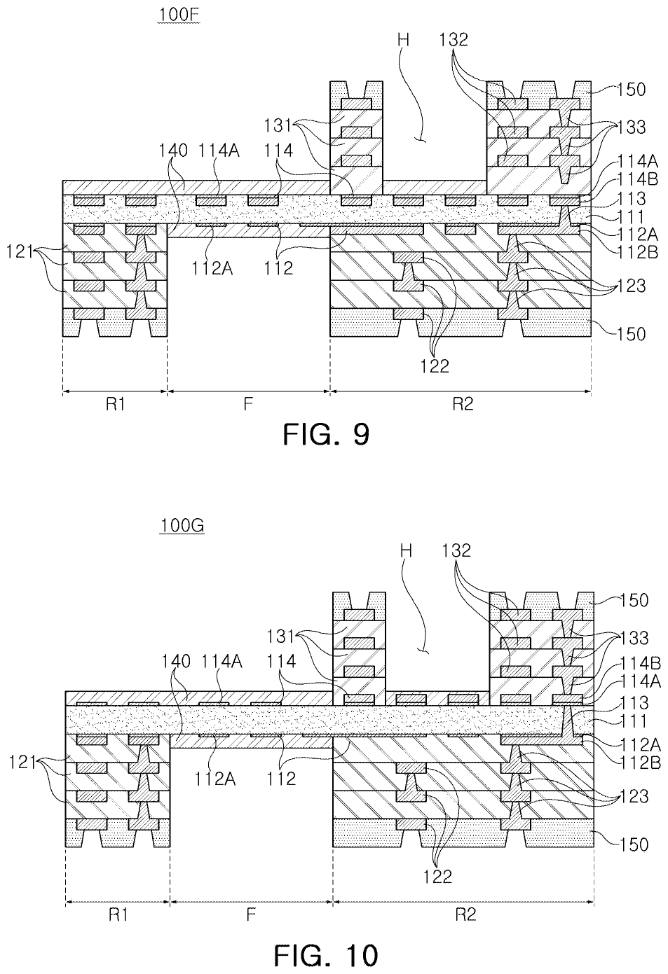

FIG. 7 is a cross-sectional view schematically illustrating another example of a printed circuit board according to the present disclosure.

Referring to the drawings, a printed circuit board 100D according to another example may include only a rigid region R, and may not include a third insulating layer 131, a fourth wiring layer 132, and a third via 133, as compared to the printed circuit board 100A according to the example.

This is illustrative that a printed circuit board according to the present disclosure may be deformed to have various forms, and the printed circuit board according to the present disclosure is not limited to the printed circuit board illustrated in the drawings.

Since other descriptions may be applied in the same manner as the descriptions of the printed circuit board 100A according to an example, detailed descriptions thereof will be omitted.

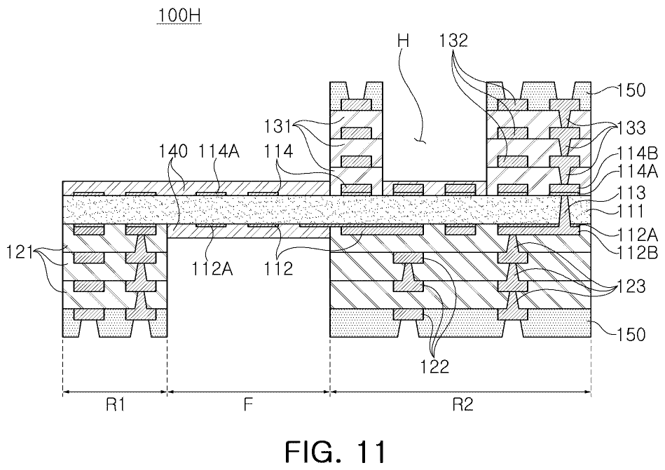

FIG. 8 is a cross-sectional view schematically illustrating another example of a printed circuit board according to the present disclosure.

Referring to the drawings, a printed circuit board 100E according to another example may include only a rigid region R, and may not include a second insulating layer 121, a third wiring layer 122, and a second via 123, as compared to the printed circuit board 100A according to the example.

This is illustrative that a printed circuit board according to the present disclosure may be deformed to have various forms, and the printed circuit board according to the present disclosure is not limited to the printed circuit board illustrated in the drawings.

Since other descriptions may be applied in the same manner as the descriptions of the printed circuit board 100A according to an example, detailed descriptions thereof will be omitted.

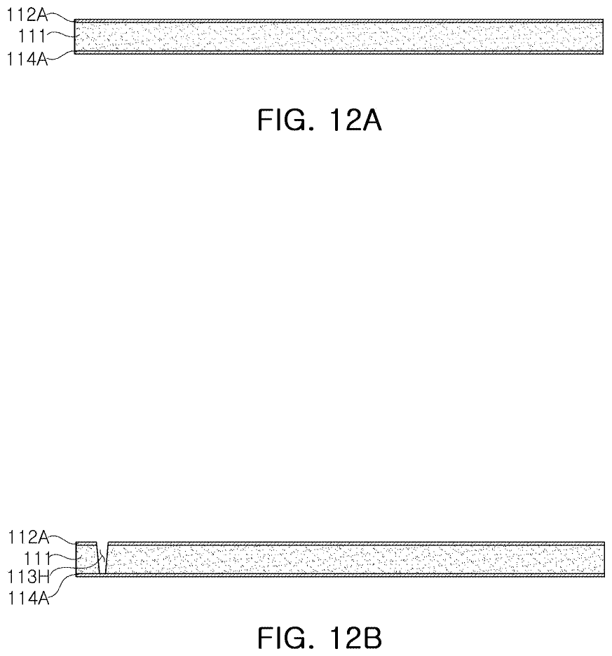

FIG. 9 is a cross-sectional view schematically illustrating another example of a printed circuit board according to the present disclosure.

Referring to the drawings, a printed circuit board 100F according to another example may have a structure in which a second wiring layer 114 is embedded in the other surface of a first insulating layer 111, as compared to the printed circuit board 100A according to the example. The second wiring layer 114 may include a first metal layer 114A and a second metal layer 114B, but is not limited thereto, and may include only a single metal layer. In addition, in one example, a stacking direction of the first metal layer 114A and the second metal layer 114B in the printed circuit board 100F may be opposite to a stacking direction of the first metal layer 114A and the second metal layer 114B in the printed circuit board 100A, with respect to the first insulating layer 111.

This is illustrative that a printed circuit board according to the present disclosure may be deformed to have various forms, and the printed circuit board according to the present disclosure is not limited to the printed circuit board illustrated in the drawings.

Since other descriptions may be applied in the same manner as the descriptions of the printed circuit board 100A according to an example, detailed descriptions thereof will be omitted.

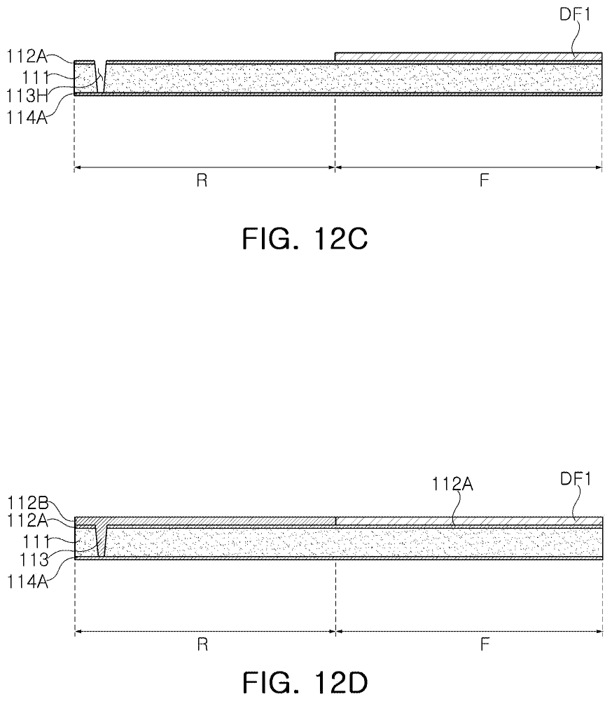

FIG. 10 is a cross-sectional view schematically illustrating another example of a printed circuit board according to the present disclosure.

Referring to the drawings, in a printed circuit board 100G according to another example, a first wiring layer 112 in a portion of a rigid region R2 may include a first metal layer 112A, and the first wiring layer 112 in other portions of the rigid region R2 may include the first metal layer 112A and a second metal layer 112B, as compared to the printed circuit board 100A according to the example.

For example, as illustrated in the drawings, a first wiring layer 112, connected to a first via 113, in a rigid region R2 includes a first metal layer 112A and a second metal layer 112B, and the first wiring layer 112, not connected to the first via 113, in the rigid region R2 may include only the first metal layer 112A. At least a portion of the first wiring layer 112, not connected to the first via 113, may also include the first metal layer 112A and the second metal layer 112B.

Such a structure may be derived by changing a manufacturing process of a printed circuit board to be described later. For example, depending on a position of a dry film, a first wiring layer 112 of a rigid region R2 may also have a portion that does not include a second metal layer 112B.

Since other descriptions may be applied in the same manner as the descriptions of the printed circuit board 100A according to an example, detailed descriptions thereof will be omitted.

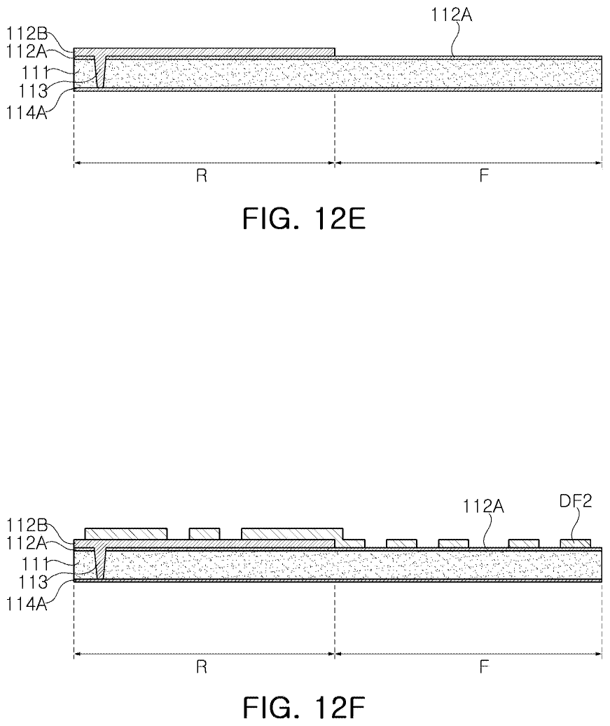

FIG. 11 is a cross-sectional view schematically illustrating another example of a printed circuit board according to the present disclosure.

Referring to the drawings, a printed circuit board 100H according to another example may have a partially different structure of a wiring pattern of a first wiring layer 112 extending to and disposed in a flexible region F and a rigid region R2, as compared to the printed circuit board 100A according to the example.

Specifically, a wiring pattern of a first wiring layer 112 extending to and disposed in a flexible region F and a rigid region R2 may include only a first metal layer 112A in the rigid region R2 adjacent to a boundary of the flexible region F and the rigid region R2. Therefore, the wiring pattern may include only the first metal layer 112A in a portion of the rigid region R2, and may include the first metal layer 112A and the second metal layer 112B in other portions of the rigid region R2.

Such a structure may be derived by changing a manufacturing process of a printed circuit board to be described later. For example, depending on a position of a dry film, a first wiring layer 112 of a rigid region R2 may also have a portion that does not include a second metal layer 112B.

Since other descriptions may be applied in the same manner as the descriptions of the printed circuit board 100A according to an example, detailed descriptions thereof will be omitted.

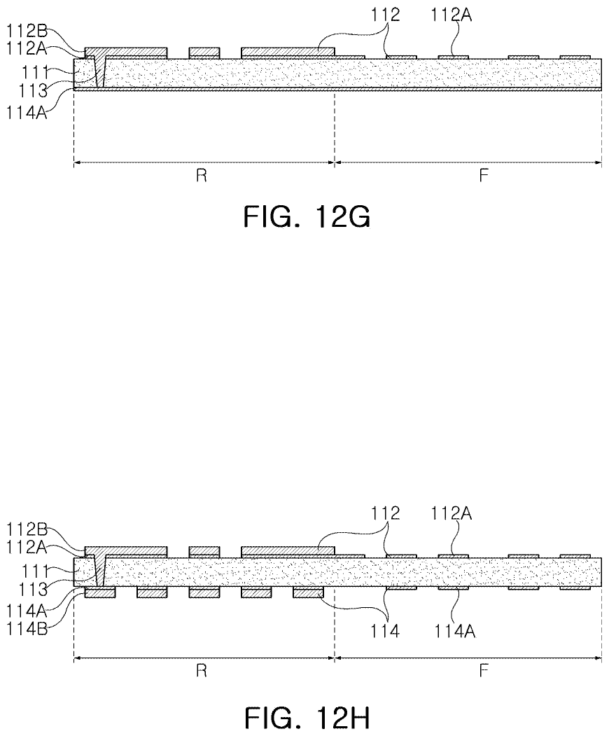

FIGS. 12A to 12H are cross-sectional views schematically illustrating a portion of a manufacturing process of a printed circuit board according to the present disclosure.

Referring to FIG. 12A, a first insulating layer 111 to which first metal layers 112A and 114A are attached to both surfaces thereof may be prepared. In this case, a copper clad laminate having copper foils attached to both surfaces of an insulating plate may be used.

Referring to FIG. 12B, a first via hole 113H passing through the first insulating layer 111 and the first metal layer 112A disposed on one surface of the first insulating layer 111 may be formed. In this case, the first metal layer 114A disposed on the other surface of the first insulating layer 111 may remain without being processed. The first via hole 113H may be formed by a laser drill, but is not limited thereto, and a known method may be used.

Referring to FIG. 12C, a dry film DF1 may be disposed to perform plating. In this case, the dry film DF1 may function as a plating resist, and the dry film DF1 may be disposed on a portion of the first metal layer 112A disposed in a region corresponding to a flexible region F.

Referring to FIG. 12D, a second metal layer 112B may be formed on a portion of the first metal layer 112A disposed in a region corresponding to a rigid region R. The second metal layer 112B may be formed through a known plating process, and may be formed by electrolytic plating, for example.

Referring to FIG. 12E, the dry film DF1 may be removed. The dry film DF1 may be removed by a peeling method or the like.

Referring to FIG. 12F, a dry film DF2 may be disposed to form a wiring pattern. The dry film DF2 may function as an etching resist, and may be disposed in a region other than a region in which the wiring pattern is formed.

Referring to FIG. 12G, a portion of the first metal layer 112A and a portion of the second metal layer 112B, disposed in a region other than a region in which the wiring pattern is formed, may be etched, and the dry film DF2 may be removed. The dry film DF2 may also be removed by a peeling method or the like.

Referring to FIG. 12H, a wiring pattern may be formed on the other surface of the first insulating layer 111 by a known plating process or the like. In this case, the wiring pattern may be formed by the same method as the method performed on the one surface of the first insulating layer 111, but is not limited thereto.

A manufacturing process of a printed circuit board according to the present disclosure is not limited to the above-described method. In order to provide a printed circuit board according to the present disclosure, a manufacturing process different from the above-described method may be applied.

As used herein, the term “connect” or “connection” in the present specification may not be only a direct connection, but also a concept including an indirect connection. In addition, the term “electrically connected” or “electrical connection” in the present specification is a concept including both a physical connection and a physical non-connection.

In the present specification, the expressions of “first,” second,” etc. in the present specification are used to distinguish one component from another, and do not limit the order and/or importance of the components. In some cases, without departing from the spirit of the present disclosure, a “first” component may be referred to as a “second” component, and similarly, a “second” component may be referred to as a “first” component.

The expression “example” used in this specification does not refer to the same embodiment to each other, but may be provided for emphasizing and explaining different unique features. However, the above-mentioned examples do not exclude that the above-mentioned examples are implemented in combination with the features of other examples. For example, although the description in a specific example is not described in another example, it can be understood as an explanation related to another example, unless otherwise described or contradicted by the other example.

The terms used in the present disclosure are used only to illustrate various examples and are not intended to limit the present inventive concept. Singular expressions include plural expressions unless the context clearly dictates otherwise.

As one of the various effects of the present disclosure, a printed circuit board capable of preventing occurrence of overhang defects may be provided.

As another effect of the various effects of the present disclosure, a printed circuit board capable of preventing occurrence of via opening defects may be provided.

As another effect of the various effects of the present disclosure, a printed circuit board capable of preventing occurrence of disconnection of a wiring layer may be provided.

While example embodiments have been illustrated and described above, it will be apparent to those skilled in the art that modifications and variations could be made without departing from the scope of the present disclosure as defined by the appended claims.

1. A printed circuit board comprising:
a plurality of insulating layers arranged in a stacking direction and defining a flexible region and a rigid region relatively arranged in a direction perpendicular to the stacking direction, the rigid region having more insulating layers, among the plurality of insulating layers, arranged in the stacking direction than the flexible region;
a first insulating layer, among the plurality of insulating layers, disposed in the flexible region and the rigid region; and
a first wiring layer disposed on one surface of the first insulating layer in the rigid region and the flexible region,
wherein a thickness of the first wiring layer in at least a portion of the rigid region is greater than a thickness of the first wiring layer in the flexible region.

2. The printed circuit board of claim 1, wherein the first wiring layer in the flexible region comprises a first metal layer, and
the first wiring layer in the at least a portion of the rigid region comprises the first metal layer and a second metal layer disposed on the first metal layer.

3. The printed circuit board of claim 2, wherein a thickness of the second metal layer is greater than a thickness of the first metal layer.

4. The printed circuit board of claim 2, wherein in the rigid region, the first metal layer and the second metal layer have a shape corresponding to each other.

5. The printed circuit board of claim 2, further comprising a second wiring layer disposed on another surface of the first insulating layer in the rigid region, opposite to the one surface of the first insulating layer.

6. The printed circuit board of claim 5, further comprising a via passing through the first insulating layer and connecting the first wiring layer and the second wiring layer.

7. The printed circuit board of claim 6, wherein the via is integrated with the second metal layer.

8. The printed circuit board of claim 1, wherein the first wiring layer comprises a wiring pattern extending to and disposed in the flexible region and the rigid region.

9. The printed circuit board of claim 8, wherein a width of the wiring pattern at a boundary between the flexible region and the rigid region is wider than a width of the wiring pattern in the flexible region and a width of the wiring pattern in the rigid region, respectively.

10. The printed circuit board of claim 8, wherein the wiring pattern has a maximum width at a boundary between the flexible region and the rigid region.

11. The printed circuit board of claim 1, further comprising a coverlay disposed on the first insulating layer in the flexible region and covering at least a portion of the first wiring layer.

12. The printed circuit board of claim 1, further comprising:
a second insulating layer disposed on the one surface of the first insulating layer in the rigid region to cover the first wiring layer; and
a third wiring layer disposed on the second insulating layer.

13. The printed circuit board of claim 12, further comprising a protective layer disposed on the second insulating layer in the rigid region and having an opening exposing at least a portion of the third wiring layer.

14. A printed circuit board comprising:
a plurality of insulating layers arranged in a stacking direction and defining a flexible region and a rigid region relatively arranged in a direction perpendicular to the stacking direction, the rigid region having more insulating layers, among the plurality of insulating layers, arranged in the stacking direction than the flexible region;
a first insulating layer, among the plurality of insulating layers, disposed in the flexible region and the rigid region; and
a wiring pattern disposed on one surface of the first insulating layer in the rigid region and the flexible region,
wherein a width of the wiring pattern at a boundary between the flexible region and the rigid region is wider than a width of the wiring pattern in the flexible region and a width of the wiring pattern in the rigid region, respectively.

15. The printed circuit board of claim 14, wherein the wiring pattern has a maximum width at a boundary between the flexible region and the rigid region.

16. A printed circuit board comprising:
a first insulating layer disposed in a flexible region and a rigid region;
a first metal layer disposed on one surface of the first insulating layer in the rigid region and the flexible region;
a second metal layer disposed on the first metal layer in the rigid region; and
a via extending from the second metal layer, past the first metal layer, and into the first insulating layer,
wherein a first pattern of the first metal layer and a second pattern of the second metal layer are connected to the via and are contiguous with each other.

17. The printed circuit board of claim 16, wherein among the flexible region and flexible region, the second metal layer is disposed only in the rigid region.

18. The printed circuit board of claim 16, wherein the via is integrated with the second metal layer, and the first metal layer is disposed between the second metal layer and the first insulating layer.

19. The printed circuit board of claim 16, wherein the first wiring layer comprises a wiring pattern extending to and disposed in the flexible region and the rigid region.

20. The printed circuit board of claim 19, wherein a width of the wiring pattern at a boundary between the flexible region and the rigid region is wider than a width of the wiring pattern in the flexible region and a width of the wiring pattern in the rigid region, respectively.

21. The printed circuit board of claim 16, further comprising a second insulating layer disposed on the first insulating layer,
wherein among the flexible region and the rigid region, the second insulating layer is disposed only in the rigid region.

22. A printed circuit board comprising:
a first insulating layer;
a first metal layer disposed on one surface of the first insulating layer;
a second metal layer disposed on the first metal layer;
a third metal layer disposed on another surface of the first insulating layer;
a second insulating layer disposed on the one surface of the first insulating layer to cover the second metal layer;
a third insulating layer disposed on the another surface of the first insulating layer to cover the third metal layer; and
a via extending in the first insulating layer from the third metal layer, past the first metal layer, and to the second metal layer,
wherein a first pattern of the first metal layer and a second pattern of the second metal layer are connected to the via and are contiguous with each other.

23. The printed circuit board of claim 22, wherein the via is integrated with the second metal layer, and the first metal layer is disposed between the second metal layer and the first insulating layer.

24. The printed circuit board of claim 22, wherein a thickness of the second metal layer is greater than a thickness of the first metal layer and a thickness of the third metal layer.
